(19) United States
(12) Patent Application Publication
(10) Pub. No.: US 2016/0064653 A1
(43) Pub. Date: Mar. 3, 2016

(54) MAGNETIC MEMORY DEVICE AND METHOD OF MANUFACTURING THE SAME

(71) Applicants: Satoshi SETO, Seoul (KR); Shuichi TSUBATA, Seoul (KR); Masatoshi YOSHIKAWA, Seoul (KR)

(72) Inventors: Satoshi SETO, Seoul (KR); Shuichi TSUBATA, Seoul (KR); Masatoshi YOSHIKAWA, Seoul (KR)

(21) Appl. No.: 14/638,699

(22) Filed: Mar. 4, 2015

Related U.S. Application Data
(60) Provisional application No. 62/044,740, filed on Sep. 2, 2014.

(51) Int. Cl. H01L 43/08; H01L 43/02; G11C 11/16; H01L 43/12

(52) U.S. Cl. CPC H01L 43/08; H01L 43/12; H01L 43/02; G11C 11/161

(57) ABSTRACT

According to one embodiment, a method of manufacturing a magnetic memory device, includes forming a stack film including a first magnetic layer, forming a mask portion on the stack film, forming a sidewall insulating portion on a sidewall of the mask portion, etching the stack film using the mask portion and the sidewall insulating portion as a mask to form a stack structure including a first portion below the mask portion and a second portion below the sidewall insulating portion, forming an ambient insulating film enclosing the mask portion, the sidewall insulating portion and the stack structure, and etching the ambient insulating film, the sidewall insulating portion and the second portion of the stack structure using the mask portion as a mask to leave the first portion of the stack structure.

### CROSS-REFERENCE TO RELATED APPLICATIONS

This application claims the benefit of U.S. Provisional Application No. 62/044,740, filed Sep. 2, 2014, the entire contents of which are incorporated herein by reference.

### FIELD

Embodiments described herein relate generally to a magnetic memory device and a method of manufacturing the same.

### BACKGROUND

A semiconductor integrated circuit device (a magnetic memory device) using as storage elements magnetoresistive effect elements is proposed. Every magnetoresistive effect element has a stack structure, which comprises a plurality of layers, including magnetic layers. The stack structure will be obtained by etching a stack film including magnetic layers.

However, the stack film includes conductive materials. Therefore, there is a possibility that the etched conductive material may adhere to the sidewall surface of the stack structure. As a result, it may happen that the sidewall surface of the stack structure where the conductive material has adhered will be conductive.

Therefore, it is desired to provide a magnetic memory device, which is capable of preventing the sidewall surface of the stack structure from becoming conductive, and a method of manufacturing the same.

### BRIEF DESCRIPTION OF THE DRAWINGS

FIG. 1 is a cross-sectional view in schematic form partially depicting the manufacturing method of a magnetic memory device in one embodiment;

FIG. 2 is a cross-sectional view in schematic form partially depicting the manufacturing method of the magnetic memory device in the embodiment;

FIG. 3 is a cross-sectional view in schematic form partially depicting the manufacturing method of the magnetic memory device in the embodiment;

FIG. 4 is a cross-sectional view in schematic form partially depicting the manufacturing method of the magnetic memory device in the embodiment;

FIG. 5 is a cross-sectional view in schematic form partially depicting the manufacturing method of a magnetic memory device in the embodiment;

FIG. 6 is a cross-sectional view in schematic form partially depicting the manufacturing method of the magnetic memory device in the embodiment;

FIG. 7 is a cross-sectional view in schematic form depicting the structure of a magnetic memory device in a modification of the embodiment; and

FIG. 8 is a view schematically showing a general structure of a semiconductor integrated circuit device in which a magnetoresistive effect element is employed.

### DETAILED DESCRIPTION

In general, according to one embodiment, a method of manufacturing a magnetic memory device, includes: forming a stack film including a first magnetic layer on an underlying region including an underlying insulating film and a bottom electrode provided in the underlying insulating film; forming a mask portion on the stack film; forming a sidewall insulating portion on a sidewall of the mask portion; etching the stack film using the mask portion and the sidewall insulating portion as a mask to form a stack structure including a first portion located below the mask portion and a second portion located below the sidewall insulating portion; forming an ambient insulating film enclosing the mask portion, the sidewall insulating portion and the stack structure; and etching the ambient insulating film, the sidewall insulating portion and the second portion of the stack structure using the mask portion as a mask to leave the first portion of the stack structure.

Now, embodiments will be explained below with reference to the drawings.

FIG. 1-FIG. 6 are cross-sectional views schematically depicting the manufacturing method of a magnetic memory device in an embodiment.

First of all, as illustrated in FIG. 1, an underlying region 10 is formed on a semiconductor substrate, which is not illustrated in any of the drawings. The underlying region 10 includes an underlying insulating film 11 and a bottom electrode 12 provided in the underlying insulating film 11. The underlying insulating film 11 is made from silicon nitride. It is possible to make the underlying insulating film 11 from silicon oxide. The bottom electrode 12 is made from tantalum (Ta). Transistors (not illustrated in any of the drawings), including a select transistor for selecting a magnetoresistive effect element, are formed on the surface area of the semiconductor substrate. It should be noted here that the magnetoresistive effect element may be occasionally referred to as a magnetic tunnel junction element (an MTJ element) in the following explanation.

Next, a stack film 20 including a first magnetic layer functioning as a magnetic storage layer is formed on the underlying region 10. The stack film 20 includes a magnetic storage layer (a first magnetic layer) 21 having a variable magnetization, a reference layer (a second magnetic layer) 22 having a fixed magnetization, and a tunnel barrier layer (a nonmagnetic layer) 23 between the magnetic storage layer 21 and the reference layer 22. The stack film 20 also includes an under layer 24 provided between the underlying region 10 and the magnetic storage layer 21 and a shift canceling layer 25 provided on the reference layer 22.

For instance, the magnetic storage layer 21, the reference layer 22 and the shift canceling layer 25 individually include a magnetic material such as Co, Fe, Ni, and the tunnel barrier layer 23 is made of MgO or AlO. The under layer 24 is made from a desired electro-conductive material.

Next, a hard mask 31 is formed as a mask portion on the stack film 20 using a predetermined electro-conductive material. Specifically, the hard mask 31 is made from tantalum (Ta), tantalum nitride (TaN), titanium nitride (TiN), tungsten (W), or diamond like carbon (DLC). Alternatively, it is possible to make the hard mask 31 from an alloy of these electro-conductive materials.

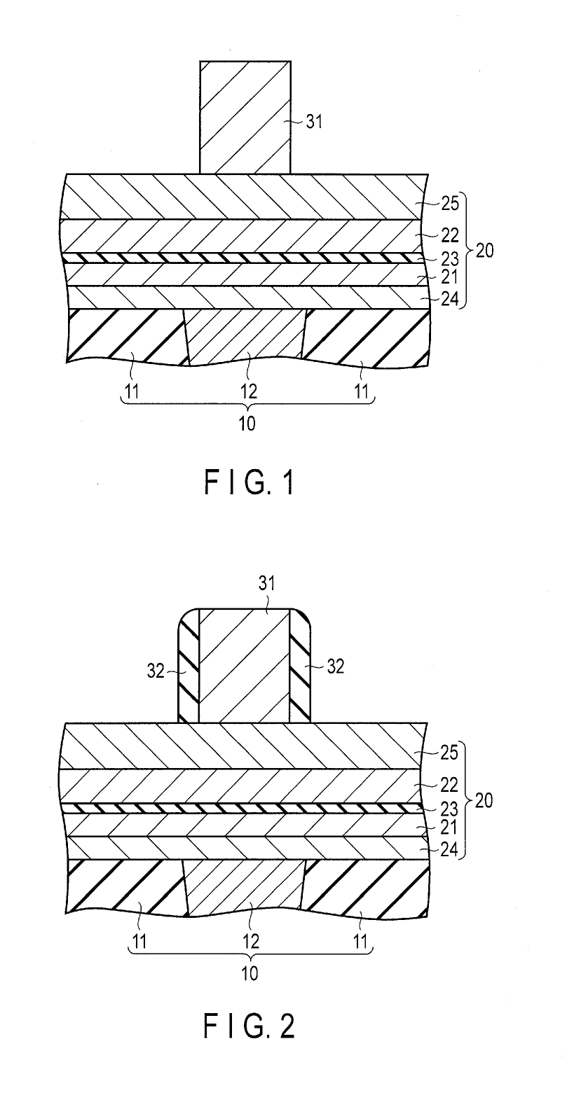

Next, as illustrated in FIG. 2, sidewall insulating portion 32 is formed on the sidewall of the hard mask 31 (the mask portion). Specifically, an insulating film covering the stack film 20 and the hard mask 31 is formed and is anisotropically etched to selectively form sidewall insulating portion 32 on the sidewall of the hard mask 31. The sidewall insulating portion 32 is made from silicon oxide. It is possible to make the sidewall insulating portion 32 from silicon nitride.

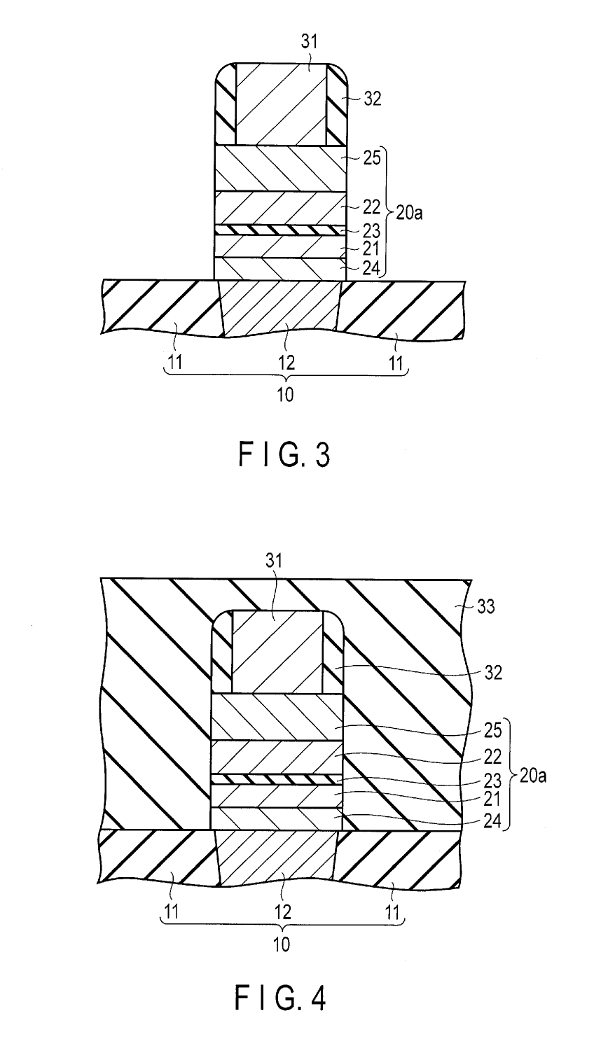

Next, the stack film 20 is etched using as a mask not only the hard mask 31 but also the sidewall insulating portion 32, and a stack structure 20a is obtained as illustrated in FIG. 3. The stack structure 20a includes a first portion located below the hard mask 31 and a second portion located below the sidewall insulating portion 32. The etching is executed by reactive ion etching (RIE) using a fluorine-based gas, for instance. While the etching is being executed, the constituent materials of the stack film 20 will be produced and may redeposit on the sidewall surface of the stack structure 20a. Therefore, the redeposited materials may adhere to the sidewall surface of the stack structure 20a. Furthermore, the exposed surface of the underlying insulating film 11 may sustain damage from the etching such as knocking.

Next, as illustrated in FIG. 4, an ambient insulating film 33 is formed which surrounds the hard mask 31, the sidewall insulating portion 32 and stack structure 20a. Specifically, an insulating film covering the hard mask 31, the sidewall insulating portion 32 and the stack structure 20a is formed on the entire structure, and the insulating film is planarized. The ambient insulating film 33 is thus obtained. The ambient insulating film 33 is made from silicon oxide. It is possible to make the ambient insulating film 33 from silicon nitride. It is desirable that the sidewall insulating portion 32 and the ambient insulating film 33 should be made from the same materials.

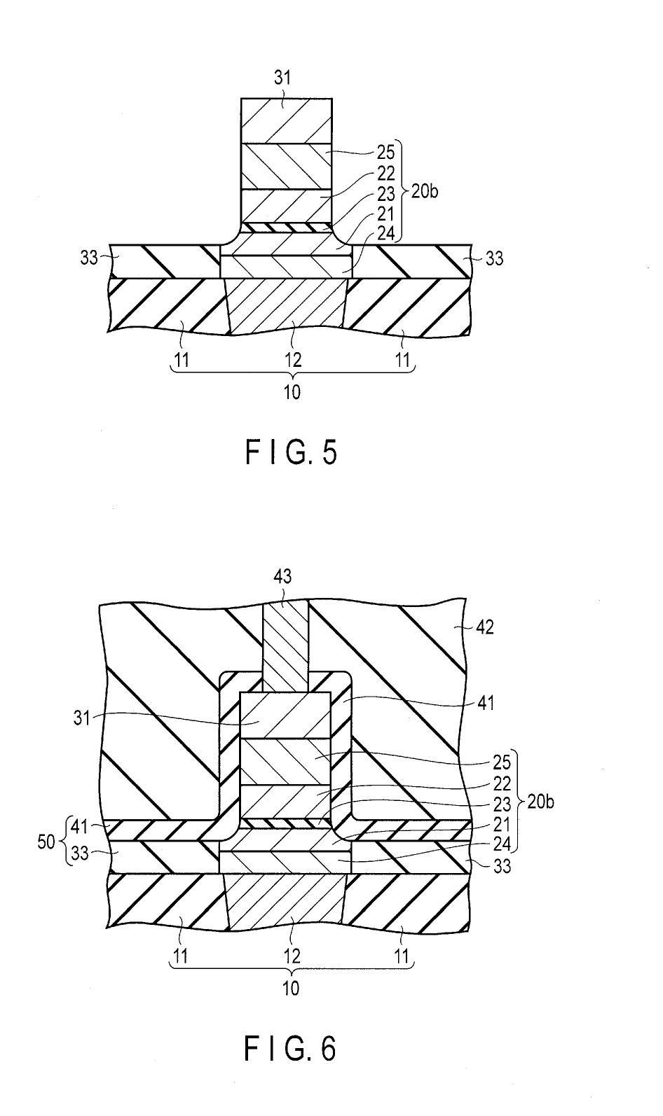

Next, as illustrated in FIG. 5, the first portion of the stack structure 20a (the portion of the stack structure 20a that is below the hard mask 31) is left by etching the ambient insulating film 33, the sidewall insulating portion 32 and the second portion of the stack structure 20a (the portion of the stack structure that is below the sidewall insulating portion 32) using the hard mask 31 as a mask. As a result, a stack structure 20b corresponding to the first portion of the stack structure 20a will be obtained.

The etching process illustrated in FIG. 5 is executed by ion beam etching (IBE). In this etching process, the etching rate of the hard mask 31 is the lowest and the etching rate of the sidewall insulating portion 32 and the ambient insulating film 33 is the highest among the hard mask 31, the sidewall insulating portion 32, the ambient insulating film 33 and the stack structure 20a.

The second portion of the stack structure 20a (the portion of the stack structure 20a that is below the sidewall insulating portion 32) is etched by the etching process illustrated in FIG. 5. Therefore, the redeposited materials having adhered to the sidewall surface of the stack structure 20a in the process illustrated in FIG. 3 will be removed by the etching process illustrated in FIG. 5. It may happen that the sidewall surface of the stack structure will be conductive if the redeposited materials adhering to it should remain there, since the redeposited material is conductive. The etching process illustrated in FIG. 5 will reliably remove the redeposited conductive materials, so that the above problem will be prevented.

It should be noted here that the second portion of the stack structure 20a (the portion of the stack structure 20a that is below the sidewall insulating portion 32) is etched by the etching process illustrated in FIG. 5. However, the etched amount is very small. Therefore, the conductive constituent materials of the stack structure 20a will barely adhere to the sidewall surface of the stack structure 20b. In the etching process of FIG. 5, the sidewall insulating portion 32 and the ambient insulating film 33 are mainly removed. Therefore, the constituent materials of the sidewall insulating portion 32 and the ambient insulating film 33 may adhere to the sidewall surface of the stack structure 20b. However, the constituent materials of the sidewall insulating portion 32 and the ambient insulating film 33 are insulating materials. Therefore, the problem that the sidewall surface of the stack structure 20b will be conductive will never happen.

Furthermore, in the etching process of FIG. 5, a portion of the ambient insulating film 33 will remain on the underlying region 10. Therefore, the bottom electrode 12 is not exposed, even after the etching process of FIG. 5 has been completed. Accordingly, the constituent materials (conductive materials) of the bottom electrode 12 will be prevented from adhering to the sidewall surface of the stack structure 20b.

Next, as illustrated in FIG. 6, a protective insulating film 41 which covers the hard mask 31, the stack structure 20b, and the ambient insulating film 33 remaining on the underlying region 10 is formed. Silicon nitride film is used for making the protective insulating film 41.

Then, an upper insulating film 42 is formed on the protective insulating film 41 to cover the protective insulating film 41. The upper insulating film 42 functions as an interlayer insulation film, and is made of a silicon oxide film.

Then, a hole that leads to the hard mask 31 is made in the protective insulating film 41 and the upper insulating film 42. The hole is filled with an electro-conductive material to form a top electrode 43.

In the above way, a magnetic memory device having a magnetoresistive effect element (an MTJ element) as illustrated in FIG. 6 will be obtained.

The MTJ element in the present embodiment includes a magnetic storage layer (a first magnetic layer) 21 having a variable magnetization, a reference layer (a second magnetic layer) 22 having a fixed magnetization, and a tunnel barrier layer (a nonmagnetic layer) 23 provided between the magnetic storage layer 21 and the reference layer 22. The MTJ element in the present embodiment also includes a shift canceling layer 25 provided on the reference layer 22. The shift canceling layer 25 is for applying to the magnetic storage layer 21 a magnetic field that is opposite in direction to the magnetic field applied from the reference layer 22 to the magnetic storage layer 21.

The MTJ element in the present embodiment is a magnetic element having a perpendicular magnetization. Namely, the direction in which the magnetic storage layer 21, the reference layer 22, and the shift canceling layer 25 are magnetized is perpendicular to their respective surfaces. When the magnetization direction of the magnetic storage layer 21 and that of the reference layer 22 are parallel to each other, the MTJ element will be in a low-resistance state. When the magnetization direction of the magnetic storage layer 21 and that of the reference layer 22 are antiparallel to each other, the MTJ element will be in a high-resistance state. The MTJ element can store binary data (0 or 1) according to whether it is in a low-resistance state or a high-resistance state. Furthermore, it is possible to write binary data (0 or 1) to the MTJ element according to the direction of the current flowing through it.

As illustrated in FIG. 6, the underlying region 10 and the stack structure 20b are covered with a first insulating film 50 in the magnetic memory device in the present embodiment. The first insulating film 50 comprises the ambient insulating film (a lower insulating film) 33 remaining on the underlying region 10, and the protective insulating film 41 covering the stack structure 20b and the lower insulating film 33. The first insulating film 50 is also covered with the upper insulating film 42. It should be noted that it does not matter whether the lower insulating film 33 and the protective insulating film 41 are of different kind of material or are of the same kind of material.

As apparent from FIG. 6, the first insulating film 50 on the underlying insulating film 11 has a stack structure comprising the lower insulating film 33 and the protective insulating film 41. Therefore, a portion of the first insulating film 50 located between the underlying insulating film 11 and the upper insulating film 42, is thicker than a portion of the first insulating film 50 located between the stack structure 20b and the upper insulating film 42 (between the upper surface of the stack structure 20b and the upper insulating film 42 and between the side surface of the stack structure 20b and the upper insulating film 42).

As having been explained above, the stack structure 20a is first formed in the step of FIG. 3, and the stack structure 20b is thereafter formed in the step of FIG. 5 in the present embodiment. In addition, the amount by which the stack structure 20a is etched in the step of FIG. 5 is very small. Moreover, what is mainly etched is the insulating material. Therefore, what may adhere to the sidewall surface of the stack structure 20b will be insulating material. This means that the problem that the sidewall surface of the stack structure 20b will be conductive may be prevented. The present embodiment therefore makes it possible to obtain a magnetic memory device that reliably prevents the sidewall surface of the stack structure from becoming conductive and thus is excellent in reliability.

Furthermore, the ambient insulating film 33 may partly remain on the underlying region 10 in the etching process of FIG. 5. Therefore, the bottom electrode 12 is not exposed, even after the etching process of FIG. 5 has been completed. As a result, the constituent materials (conductive materials) of the bottom electrode 12 will be prevented from adhering to the sidewall surface of the stack structure 20b. Accordingly, the sidewall surface of the stack structure will be prevented from becoming conductive in this way.

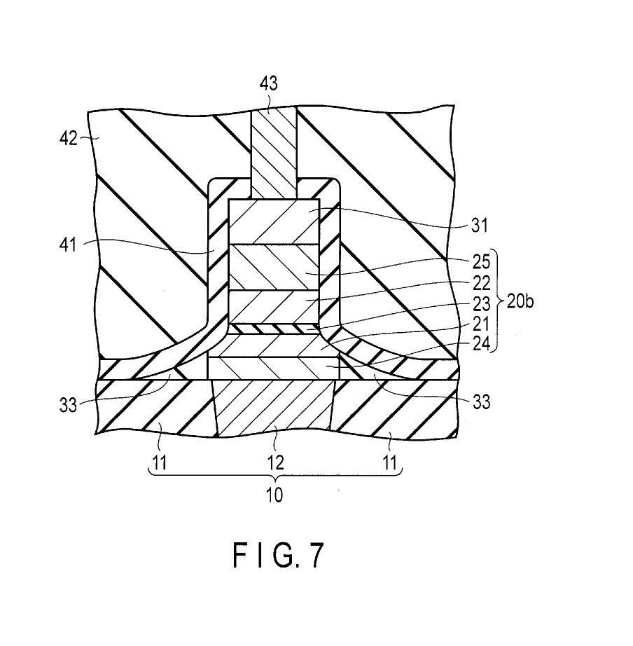

In any of the aforementioned embodiments, the shape of the ambient insulating film (the lower insulating film) 33 remaining on the underlying region 10 in the step of FIG. 5 has not been specifically explained. In the step of FIG. 5, the stack structure 20b is generally etched to have a tapered lower layer portion. Therefore, as illustrated in FIG. 7, there is a case in which the lower insulating film 33 will be formed to be tapered. Even in such a case the bottom electrode 12 is not exposed after the etching process of FIG. 5, so that the constituent materials (conductive materials) of the bottom electrode 12 will be prevented from adhering to the sidewall surface of the stack structure 20b.

In any of the above mentioned embodiments, the conductive material will barely adhere to the sidewall surface of the stack structure 20b formed in the step of FIG. 5, as having been described above. Therefore, even if an oxidation process for making the conductive redeposited materials nonconductive is not executed, the sidewall surface of the stack structure 20b will be insulated. To make much sure of the insulation property of the sidewall surface of the stack structure 20b, the oxidation treatment may be performed to the sidewall surface of the stack structure 20b after the stack structure 20b has been formed in the step of FIG. 5. Even in such a case, it may suffice to perform a very weak oxidation treatment so that it is possible to minimize the damage which the sidewall surface will sustain from the oxidation treatment.

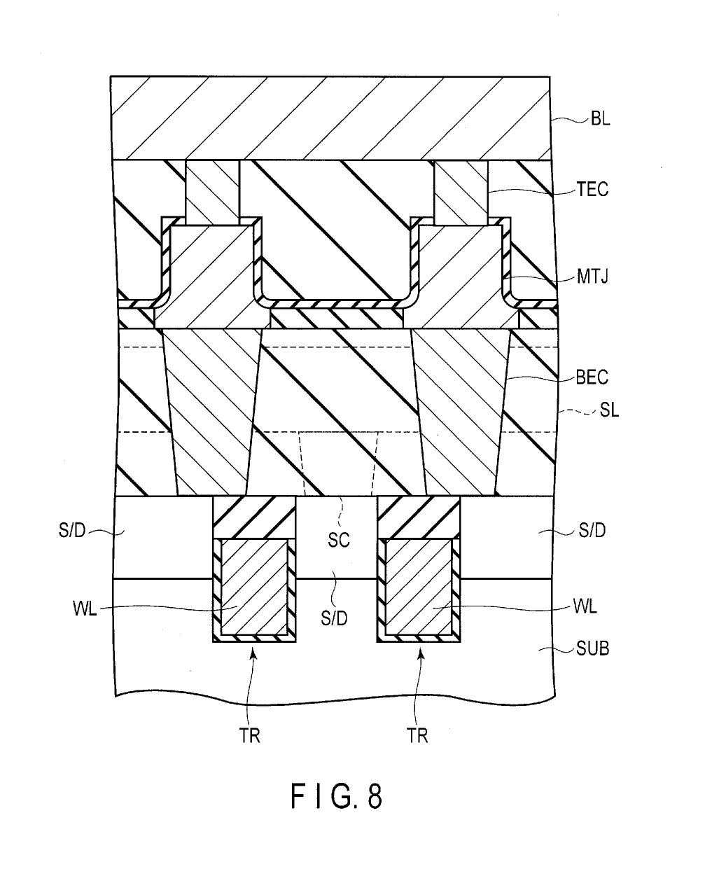

FIG. 8 is a view schematically showing a general structure of a semiconductor integrated circuit device in which a magnetoresistive effect element (MTJ element) is employed.

A buried gate type MOS transistor TR is formed in a semiconductor substrate SUB. A gate electrode of the MOS transistor TR is used as a word line WL. A bottom electrode BEC is connected to one of source/drain regions S/D of the MOS transistor TR, and a source line contact SC is connected to the other of the source/drain regions S/D.

A magnetoresistive effect element MTJ is formed on the bottom electrode BEC, and a top electrode TEC is formed on the magnetoresistive effect element MTJ. A bit line BL is connected to the top electrode TEC. A source line SL is connected to the source line contact SC.

An excellent semiconductor integrated circuit device can be obtained by applying the structure and the method described in the above embodiment to the semiconductor integrated circuit device shown in FIG. 8.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a magnetic memory device, comprising:
forming a stack film including a first magnetic layer on an underlying region including an underlying insulating film and a bottom electrode provided in the underlying insulating film;
forming a mask portion on the stack film;
forming a sidewall insulating portion on a sidewall of the mask portion;
etching the stack film using the mask portion and the sidewall insulating portion as a mask to form a stack structure including a first portion located below the mask portion and a second portion located below the sidewall insulating portion;
forming an ambient insulating film enclosing the mask portion, the sidewall insulating portion and the stack structure; and
etching the ambient insulating film, the sidewall insulating portion and the second portion of the stack structure using the mask portion as a mask to leave the first portion of the stack structure.

2. The method of claim 1, wherein part of the ambient insulating film remains on the underlying region in etching the ambient insulating film, the sidewall insulating portion and the second portion of the stack structure.

3. The method of claim 2, further comprising forming a protective insulating film covering the mask portion, the first portion of the stack structure, and the part of the ambient insulating film left on the underlying region.

4. The method of claim 3, further comprising forming an upper insulating film covering the protective insulating film.

5. The method of claim 1, wherein the bottom electrode is not exposed in etching the ambient insulating film, the sidewall insulating portion and the second portion of the stack structure.

6. The method of claim 1, wherein etching the ambient insulating film, the sidewall insulating portion and the second portion of the stack structure is performed by IBE.

7. The method of claim 1, wherein the sidewall insulating portion and the ambient insulating film are formed of the same kind of material.

8. The method of claim 1, wherein the sidewall insulating portion is made from silicon oxide or silicon nitride.

9. The method of claim 1, wherein the ambient insulating film is made from silicon oxide or silicon nitride.

10. The method of claim 1, wherein the stack film includes the first magnetic layer having a variable magnetization, a second magnetic layer having a fixed magnetization, and a nonmagnetic layer provided between the first magnetic layer and the second magnetic layer.

11. A magnetic memory device comprising:
an underlying region including an underlying insulating film and a bottom electrode provided in the underlying insulating film;
a stack structure formed on the underlying region and including a first magnetic layer;
a first insulating film covering the underlying region and the stack structure; and
an upper insulating film covering the first insulating film,
wherein a portion of the first insulating film located between the underlying insulating film and the upper insulating film is thicker than a portion of the first insulating film located between the stack structure and the upper insulating film.

12. The device of claim 11, further comprising a portion formed on the stack structure and aligned with the stack structure.

13. The device of claim 11, wherein the first insulating film includes a lower insulating film formed on the underlying insulating film, and a protective insulating film covering the stack structure and the lower insulating film.

14. The device of claim 13, wherein the lower insulating film and the protective insulating film are formed of a different kind of material.

15. The device of claim 13, wherein the lower insulating film and the protective insulating film are formed of the same kind of material.

16. The device of claim 13, wherein the lower insulating film is made from silicon oxide or silicon nitride.

17. The device of claim 13, wherein the protective insulating film is made from silicon nitride.

18. The device of claim 11, wherein the stack structure includes a first magnetic layer having a variable magnetization, a second magnetic layer having a fixed magnetization, and a nonmagnetic layer provided between the first magnetic layer and the second magnetic layer.
